(19) United States
(12) Patent Application Publication
(10) Pub. No.: US 2003/0057573 A1
(43) Pub. Date: Mar. 27, 2003

(54) Semiconductor device

(75) Inventors: Toshitaka Sekine, Kanagawa (JP); Tetsuji Hori, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/251,763

(22) Filed: Sep. 23, 2002

(30) Foreign Application Priority Data
Sep. 26, 2001 (JP) 2001-293339

(51) Int. Cl. H01L 21/44; H01L 23/10; H01L 23/28

(52) U.S. Cl. 257/787; 438/112; 257/796; 438/124; 257/723; 438/109; 257/706

(57) ABSTRACT

A semiconductor device according to an aspect of the present invention includes a lead frame formed substantially on a single plane, a power semiconductor element and a control semiconductor element mounted on the lead frame, a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted. The heat sink is spaced apart from the lead frame at a periphery portion thereof so that a distance between the heat sink and the lead frame is gradually increased in a direction perpendicular to the surface of the lead frame on which the power semiconductor element and the control semiconductor element are mounted.

### CROSS-REFERENCE TO RELATED APPLICATIONS

This application is based upon and claims the benefit of priority from the prior Japanese Patent Application No. 2001-293339, filed on Sep. 26, 2001, the entire contents of which are incorporated herein by reference.

### BACKGROUND OF THE INVENTION

1. Field of the Invention

The present invention relates to semiconductor devices. In particular, the present invention relates to an intelligent power module of resin-sealing type.

2. Related Background Art

FIG. 4 shows a section view of a conventional semiconductor device, including a lead frame 1, a power semiconductor element 2 and a control semiconductor element 3 mounted on the lead frame 1, a wire 4 of Al electrically connecting the lead frame 1 and the power semiconductor element 2, a wire 5 of Au electrically connecting the lead frame 1 and the control semiconductor element 3, and a heat sink 7 bonded via an insulating layer 8 to the lead frame 1 at the side opposite to the side on which the power semiconductor element 2 and the control semiconductor element 3 are mounted. The entire device is sealed with a sealing resin 6.

When this type of conventional semiconductor device is fabricated, first the power semiconductor element 2 and the control semiconductor element 3 are mounted on the lead frame 1, and connected with the lead frame 1 with the wire 4 of Al and the wire 5 of Au, respectively. Then, at the same time as the heat sink 7, on which the insulating layer 8 is formed, is bonded to the lead frame 1, the entire device is transfer molded with the sealing resin 6. At the time of the transfer molding, however, there is a problem in that the sealing resin 6 cannot be fully filled around the interface between the insulating layer 8 and the surface of the lead frame 1, at the side opposite to the side on which the power semiconductor element 2 is mounted, resulting in that it is not possible to secure the insulation between the lead frame 1 and the heat sink 7.

### BRIEF SUMMARY OF THE INVENTION

According to the first aspect of the present invention, a semiconductor device includes: a lead frame formed substantially on a single plane; a power semiconductor element and a control semiconductor element mounted on the lead frame; a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted, the heat sink being spaced apart from the lead frame at a periphery portion thereof so that a distance between the heat sink and the lead frame is gradually increased in a direction perpendicular to the surface of the lead frame on which the power semiconductor element and the control semiconductor element are mounted.

According to the second aspect of the present invention, a semiconductor device includes: a lead frame; a power semiconductor element and a control semiconductor element mounted on the lead frame; a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted, the lead frame including a depressed portion formed by depressing a portion of the lead frame, on which the power semiconductor element is mounted, toward the heat sink on which the insulating layer is formed.

According to the third aspect of the present invention, a semiconductor device includes: a lead frame; a power semiconductor element and a control semiconductor element mounted on the lead frame; a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted, the heat sink gradually becoming thinner at a periphery portion thereof.

According to the fourth aspect of the present invention, a semiconductor device includes: a lead frame; a power semiconductor element and a control semiconductor element mounted on the lead frame; a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted, the heat sink including, on a side at which the insulating layer is formed, a step portion including the insulating layer so as to be gradually spaced apart from the lead frame at a periphery portion thereof.

According to the fifth aspect of the present invention, a semiconductor device includes: a lead frame; a power semiconductor element and a control semiconductor element mounted on the lead frame; a first conductor electrically connecting the power semiconductor element and the lead frame, and a second conductor electrically connecting the control semiconductor element and the lead frame; and a heat sink formed, via an insulating layer, on a surface of the lead frame at a side opposite to a side on which the power semiconductor element and the control semiconductor element are mounted, the heat sink including, on a side at which the insulating layer is formed, a tapering portion including the insulating layer so as to be gradually spaced apart from the lead frame at a periphery portion thereof.

### BRIEF DESCRIPTION OF THE DRAWINGS

FIG. 1 shows the structure of the semiconductor device according to the first embodiment of the present invention.

FIG. 2 shows the structure of the semiconductor device according to the second embodiment of the present invention.

FIG. 3 shows the structure of the semiconductor device according to the third embodiment of the present invention.

FIG. 4 shows the structure of a conventional semiconductor device.

### DETAILED DESCRIPTION OF THE INVENTION

Hereinafter, embodiments of the present invention will be described with reference to the accompanying drawings.

(First Embodiment)

FIG. 1 is a sectional view of the structure of the semiconductor device according to the first embodiment of the present invention. The semiconductor device includes a power semiconductor element 2 and a control semiconductor element 3 mounted on a lead frame 1. The lead frame 1 and the power semiconductor element 2 are electrically connected with a wire 4 of Al, and the lead frame 1 and the control semiconductor element 3 are electrically connected with a wire 5 of Au. Further, a heat sink 7 is formed via an insulating layer 8 on the lead frame 1 at the side opposite to the side on which the power semiconductor element 2 and the control semiconductor element 3 are mounted. The entire device is sealed with a sealing resin 6. A slanted step portion 7A is formed on a peripheral portion of one side of the heat sink 7, on which the insulating layer 8 is formed, so that the heat sink 7 is gradually spaced apart from the lead frame 1 at the edge portions. That is, the distance between the heat sink 7 and the lead frame 1 is gradually increased at the periphery portion in the direction perpendicular to the surface of the lead frame 1 on which the power semiconductor element 2 and the control semiconductor element 3 are mounted.

The insulating layer 8 is also formed on the step portion 7A. Further, the entire device is sealed with the sealing resin 6.

Since the slanted step portion 7A is formed around the peripheral portion of the heat sink 7, it is possible to secure the insulating distance between the lead frame 1 and the heat sink 7. Thus, at the time of transfer molding, even if the sealing resin 6 is not fully filled, it is possible to secure the insulation.

In this embodiment, the lead frame 1 is substantially on a single plane, and the heat sink 7 becomes thinner at the peripheral portion in a slanted step fashion.

(Second embodiment)

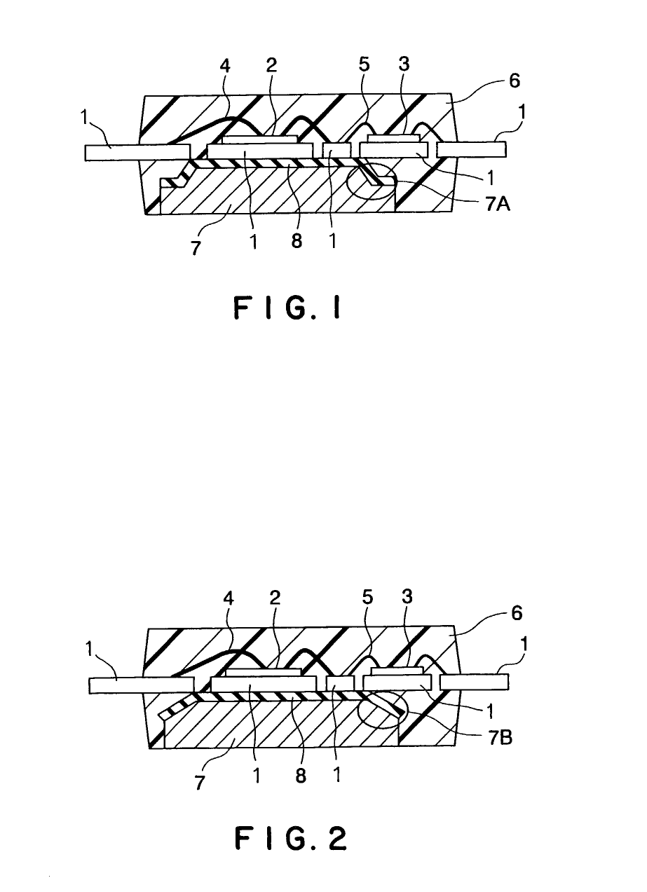

FIG. 2 shows the structure of the semiconductor device according to the second embodiment of the present invention. In the semiconductor device of this embodiment, the slanted step portion 7A of the semiconductor device of the first embodiment is replaced with a tapering portion 7B, which is gradually spaced apart from the lead frame 1 at the peripheral portion. That is, the distance between the heat sink 7 and the lead frame 1 are gradually increased at the periphery portion, in the direction perpendicular to the surface of the lead frame 1 on which the power semiconductor element 2 and the control semiconductor element 3 are mounted.

With such a structure, it is possible to secure the insulation between the lead frame 1 and the heat sink 7. Accordingly, even if the sealing resin 6 is not fully filled at the time of transfer molding, it is possible to secure the insulation.

In this embodiment, the lead frame 1 is substantially on a single plane, and the heat sink 7 becomes thinner in a tapering fashion at the peripheral portion.

(Third Embodiment)

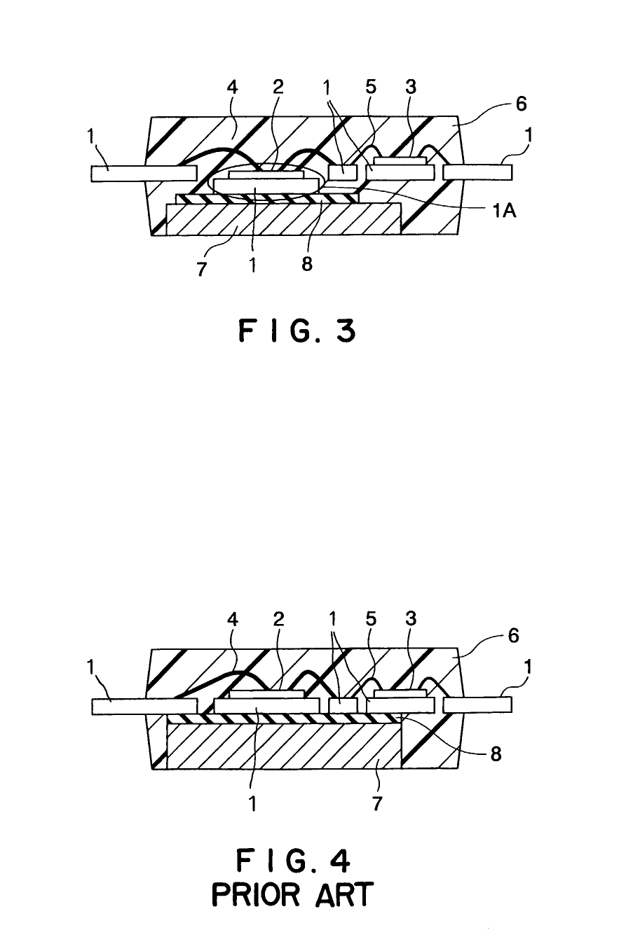

FIG. 3 shows the structure of the semiconductor device according to the third embodiment of the present invention. The semiconductor device of this embodiment is achieved by adding to the prior art device shown in FIG. 1 a depressed portion 1A formed by depressing the portion of the lead frame 1, on which the power semiconductor element 2 is mounted, toward the side of heat sink 7 on which the insulating layer 8 is formed. With this structure, it is possible to secure the insulation distance between the lead frame 1 and the heat sink 7. Thus, even if the sealing resin 6 is not fully filled in the device at the time of transfer molding, it is possible to secure the insulation.

Although the lead frame 1 and the semiconductor elements 2 and 3 are connected with the wires 4 and 5 in the first to the third embodiments, conductors such as metal plates can be used as substitutes for the wires.

As described above, according to the present invention, it is possible to secure the insulation distance between the lead frame and the heat sink.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor device comprising:
a lead frame formed substantially on a single plane;
a power semiconductor element and a control semiconductor element mounted on said lead frame;
a first conductor electrically connecting said power semiconductor element and said lead frame, and a second conductor electrically connecting said control semiconductor element and said lead frame; and
a heat sink formed, via an insulating layer, on a surface of said lead frame at a side opposite to a side on which said power semiconductor element and said control semiconductor element are mounted, said heat sink being spaced apart from said lead frame at a periphery portion thereof so that a distance between said heat sink and said lead frame is gradually increased in a direction perpendicular to the surface of said lead frame on which said power semiconductor element and said control semiconductor element are mounted.

2. The semiconductor device according to claim 1, wherein said heat sink includes, at a side on which the insulating layer is formed, a step portion so as to be gradually spaced apart from said lead frame in the periphery portion thereof.

3. The semiconductor device according to claim 1, wherein said heat sink includes, at a side on which the insulating layer is formed, a tapering portion so as to be gradually spaced apart from said lead frame in the periphery portion thereof.

4. A semiconductor device comprising:
a lead frame;
a power semiconductor element and a control semiconductor element mounted on said lead frame;
a first conductor electrically connecting said power semiconductor element and said lead frame, and a second conductor electrically connecting said control semiconductor element and said lead frame; and
a heat sink formed, via an insulating layer, on a surface of said lead frame at a side opposite to a side on which said power semiconductor element and said control semiconductor element are mounted,
said lead frame including a depressed portion formed by depressing a portion of said lead frame, on which said power semiconductor element is mounted, toward said heat sink on which the insulating layer is formed.

5. A semiconductor device comprising:
a lead frame;
a power semiconductor element and a control semiconductor element mounted on said lead frame;
a first conductor electrically connecting said power semiconductor element and said lead frame, and a second conductor electrically connecting said control semiconductor element and said lead frame; and
a heat sink formed, via an insulating layer, on a surface of said lead frame at a side opposite to a side on which said power semiconductor element and said control semiconductor element are mounted, said heat sink gradually becoming thinner at a periphery portion thereof.

6. The semiconductor device according to claim 5, wherein said heat sink includes, at a side on which the insulating layer is formed, a step portion so as to be gradually spaced apart from said lead frame in the periphery portion thereof.

7. The semiconductor device according to claim 5, wherein said heat sink includes, at a side on which the insulating layer is formed, a tapering portion so as to be gradually spaced apart from said lead frame in the periphery portion thereof.

8. A semiconductor device comprising:
a lead frame;
a power semiconductor element and a control semiconductor element mounted on said lead frame;
a first conductor electrically connecting said power semiconductor element and said lead frame, and a second conductor electrically connecting said control semiconductor element and said lead frame; and
a heat sink formed, via an insulating layer, on a surface of said lead frame at a side opposite to a side on which said power semiconductor element and said control semiconductor element are mounted, said heat sink including, on a side at which the insulating layer is formed, a step portion including the insulating layer so as to be gradually spaced apart from said lead frame at a periphery portion thereof.

9. A semiconductor device comprising:
a lead frame;
a power semiconductor element and a control semiconductor element mounted on said lead frame;
a first conductor electrically connecting said power semiconductor element and said lead frame, and a second conductor electrically connecting said control semiconductor element and said lead frame; and
a heat sink formed, via an insulating layer, on a surface of said lead frame at a side opposite to a side on which said power semiconductor element and said control semiconductor element are mounted, said heat sink including, on a side at which the insulating layer is formed, a tapering portion including the insulating layer so as to be gradually spaced apart from said lead frame at a periphery portion thereof.
